(19) United States
(12) Patent Application Publication
(10) Pub. No.: US 2024/0136324 A1
(43) Pub. Date: Apr. 25, 2024

(54) SEMICONDUCTOR MANUFACTURING METHOD

(71) Applicant: Taiwan Semiconductor Manufacturing Company, Ltd., Hsinchu (TW)

(72) Inventors: Wen-Chih CHIOU, Hsinchu (TW); Yen-Ming CHEN, Hsinchu (TW); Yung-Chi LIN, Hsinchu (TW)

(73) Assignee: Taiwan Semiconductor Manufacturing Company, Ltd., Hsinchu (TW)

(21) Appl. No.: 18/099,097

(22) Filed: Jan. 19, 2023

Related U.S. Application Data
(60) Provisional application No. 63/417,793, filed on Oct. 20, 2022.

(51) Int. Cl. H01L 23/00

(52) U.S. Cl. CPC H01L 24/83; H01L 24/27; H01L 2224/2762; H01L 2224/291; H01L 2224/29186; H01L 2224/83007

(57) ABSTRACT

A semiconductor manufacturing method is provided. The semiconductor manufacturing method includes the following steps. A first semiconductor element with a bonding film and a first stressing film is formed. The first bonding film and the first stressing film are formed on two opposite sides of the first semiconductor element. The first stressing film makes the first bonding film to have a first convex surface. A second semiconductor element with a second bonding film is formed. The second bonding film is formed on one side of the second semiconductor element. The first semiconductor element and the second semiconductor element are bonded by bonding the first bonding film and the second bonding film.

### PRIORITY CLAIM AND CROSS-REFERENCE

This application claims the benefit of U.S. provisional application Ser. No. 63/417,793, filed Oct. 20, 2022, the subject matter of which is incorporated herein by reference.

### BACKGROUND

The disclosure relates in general to a manufacturing method and more particularly to a semiconductor manufacturing method.

With the development of semiconductor technology, chip bonding technology has been developed. A chip could be bounded on a wafer or another chip. However, the phenomenon of poor bonding is often found in the process, which has become a bottleneck in the development of technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a chip bonding process in a semiconductor manufacturing method according to one embodiment.

FIG. 2 illustrates the detail steps of FIG. 1.

FIG. 3 illustrates the chip bonding process in the semiconductor manufacturing method according to another embodiment.

FIG. 4 illustrates the detail steps of FIG. 3.

FIG. 5 illustrates the chip bonding process in the semiconductor manufacturing method according to another embodiment.

FIG. 6 illustrates the detail steps of FIG. 5.

FIG. 7 illustrates the chip bonding process in the semiconductor manufacturing method according to another embodiment.

FIG. 8 illustrates the detail steps of FIG. 7.

FIG. 9 illustrates the chip bonding process in the semiconductor manufacturing method according to another embodiment.

FIG. 10 illustrates the detail steps of FIG. 9.

FIG. 11 illustrates the chip bonding process in the semiconductor manufacturing method according to another embodiment.

FIG. 12 illustrates the detail steps of FIG. 9.

FIG. 13 illustrates the chip bonding process in the semiconductor manufacturing method according to another embodiment.

FIG. 14 illustrates the chip bonding process in the semiconductor manufacturing method according to another embodiment.

FIG. 15 illustrates the chip bonding process in the semiconductor manufacturing method according to another embodiment.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

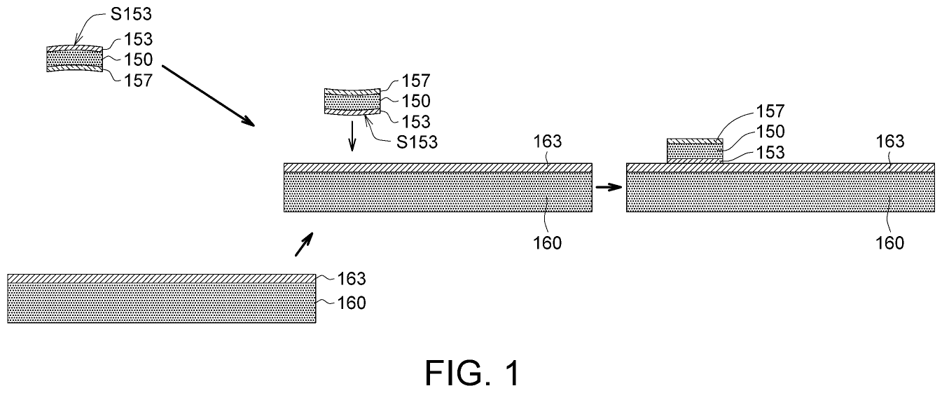

Please refer to FIG. 1, which illustrates a chip bonding process in a semiconductor manufacturing method according to one embodiment. A semiconductor element 150 with a bonding film 153 is formed, and a semiconductor element 160 with a bonding film 163 is formed. The semiconductor element 150 is bonded to the semiconductor element 160 by bonding the bonding film 153 to the bonding film 163. The semiconductor element 150 is, for example, a chip; the semiconductor element 160 is, for example, a wafer (or a chip). The material of the bonding film 153 is, for example, oxide, silicon, nitride, metal or the combination thereof. The material of the bonding film 163 is, for example, oxide, silicon, nitride, metal or the combination thereof.

Generally speaking, the quality of bonding seriously affects the yield of the semiconductor product. For example, if there is an air gap or insufficient bonding in the bonding interface, cracks may occur due to etching, high temperature or vibration in the subsequent process. Researchers are working to improve the quality of bonding.

As shown in the upper left drawing of FIG. 1, the semiconductor element 150 with the bonding film 153 and a stressing film 157 is formed. The bonding film 153 and the stressing film 157 are formed on two opposite sides of the semiconductor element 150. The stressing film 157 makes the semiconductor element 150 being warped and makes the bonding film 153 having a convex surface S153.

Further, as shown in the lower left drawing of FIG. 1, the semiconductor element 160 with the bonding film 163 is formed. The bonding film 163 is formed on one side of the semiconductor element 160.

Then, as shown in the right drawings of FIG. 1, the semiconductor element 150 and the semiconductor element 160 are bonded by bonding the bonding film 153 and the bonding film 163. When the bonding film 153 and the bonding film 163 are going to be bonded, the bonding film 153 and the bonding film 163 are in point-to-point contact first due to the convex surface S153 of the bonding film 153. Then, the contact area is gradually expanded as the bonding film 153 and the bonding film 163 approach. Therefore, any air gap would not be existed in the bonding interface, and the quality of bonding can be improved.

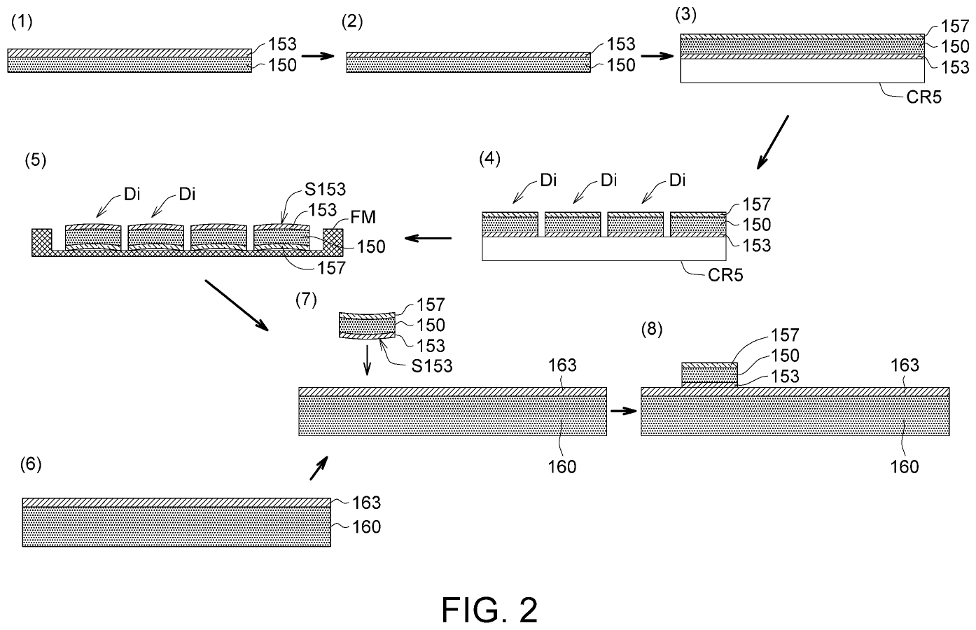

Please refer to FIG. 2, which illustrates the detail steps of FIG. 1. The drawings in FIG. 2 are labeled as “(1)” to “(8)”. As shown in the drawing labeled as “(1)” of FIG. 2, the bonding film 153 is formed on the semiconductor element 150. The bonding film 153 is, for example, formed by disposition.

Then, as shown in the drawing labeled as “(2)” of FIG. 2, the bonding film 153 is grinded by chemical mechanical polishing (CMP). In one embodiment, this step could be omitted.

Next, as shown in the drawing labeled as “(3)” of FIG. 2, the semiconductor element 150 and the bonding film 153 are turned over and carried by a temporary carrier CR5, for example a tape. The stressing film 157 is formed on the backside of the semiconductor element 150. For example, the stressing film 157 could be formed by pasting a polymer tape on the semiconductor element 150, or by depositing a polymer material on the semiconductor element 150.

Afterwards, as shown in the drawing labeled as “(4)” of FIG. 2, the stressing film 157, the semiconductor element 150 and the bonding film 153 are cut to form a plurality of chips Di. The stressing film 157, the semiconductor element 150 and the bonding film 153 could be cut by laser, or mechanical tool. In another embodiment, the steps shown in the drawings labeled as “(3)” and “(4)” could be exchanged.

Then, as shown in the drawing labeled as “(5)” of FIG. 2, the temporary carrier CR5 is removed, and the chips Di are placed on a dicing frame FM. Further, the chips Di includes the stressing film 157 could be cured. After curing, the stressing film 157 is deformed and makes the semiconductor element 150 being warped. In another embodiment, the stressing film 157 could be deformed without curing.

Further, as shown in the drawing labeled as “(6)” of FIG. 2, the bonding film 163 is formed on the semiconductor element 160. The bonding film 163 is, for example, formed by disposition. The semiconductor element 160 is, for example, a wafer.

Next, as shown in the drawing labeled as “(7)” of FIG. 2, the semiconductor element 150 is bounded on the semiconductor element 160 by bonding the bonding film 153 and the bonding film 163. When the bonding film 153 and the bonding film 163 are going to be bonded, the bonding film 153 and the bonding film 163 are in point-to-point contact first due to the convex surface S153 of the bonding film 153. Then, the contact area is gradually expanded as the bonding film 153 and the bonding film 163 approach.

Afterwards, as shown in the drawing labeled as “(8)” of FIG. 2, the semiconductor element 150 is already bonded on the semiconductor element 160, and any air gap would not be existed in the bonding interface, and the quality of bonding can be improved. The semiconductor device including the semiconductor element 150 and the semiconductor element 160 could continue to be processed by other processes.

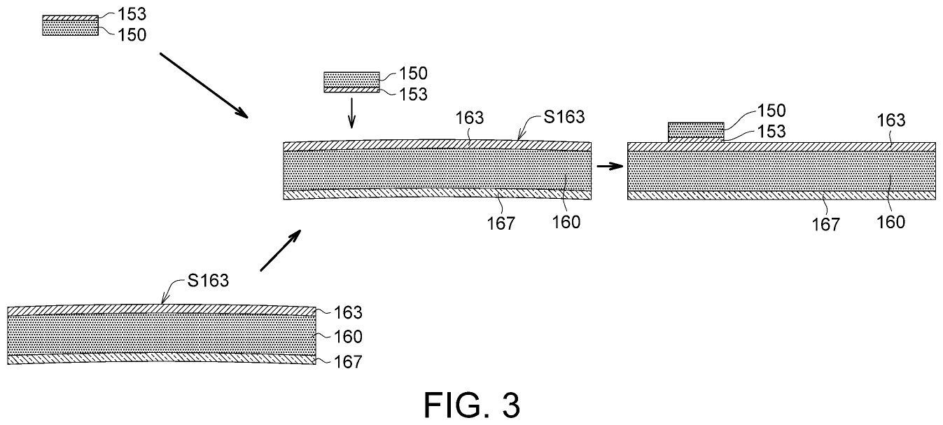

Please refer to FIG. 3, which illustrates the chip bonding process in the semiconductor manufacturing method according to another embodiment. As shown in the upper left drawing of FIG. 3, the semiconductor element 150 with the bonding film 153 is formed. The bonding film 153 is formed on one side of the semiconductor element 150.

Further, as shown in the lower left drawing of FIG. 3, the semiconductor element 160 with the bonding film 163 and a stressing film 167 is formed. The bonding film 163 and the stressing film 167 are formed on two sides of the semiconductor element 160. The stressing film 167 makes the semiconductor element 160 being warped and makes the bonding film 163 having a convex surface S163.

Then, as shown in the right drawing of FIG. 3, the semiconductor element 150 and the semiconductor element 160 are bonded by bonding the bonding film 153 and the bonding film 163. When the bonding film 153 and the bonding film 163 are going to be bonded, the bonding film 153 and the bonding film 163 are in point-to-point contact first due to the convex surface S163 of the bonding film 163. Then, the contact area is gradually expanded as the bonding film 153 and the bonding film 163 approach. Therefore, any air gap would not be existed in the bonding interface, and the quality of bonding can be improved.

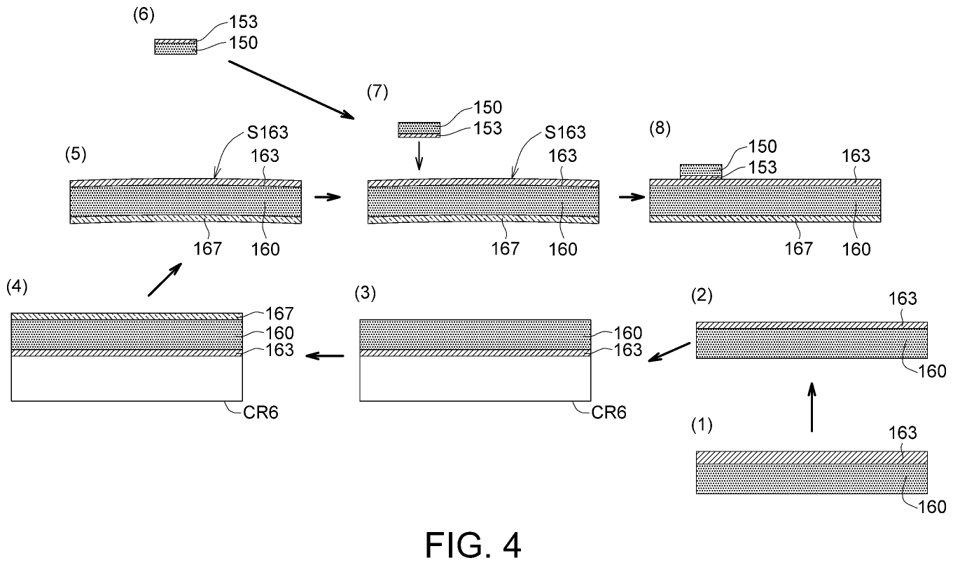

Please refer to FIG. 4, which illustrates the detail steps of FIG. 3. The drawings in FIG. 4 are labeled as “(1)” to “(8)”. As shown in the drawing labeled as “(1)” of FIG. 4, the bonding film 163 is formed on the semiconductor element 160. The semiconductor element 160 is, for example, a wafer. The bonding film 163 is, for example, formed by disposition.

Then, as shown in the drawing labeled as “(2)” of FIG. 4, the bonding film 163 is grinded by chemical mechanical polishing (CMP). In one embodiment, this step could be omitted.

Next, as shown in the drawing labeled as “(3)” of FIG. 4, the semiconductor element 160 and the bonding film 163 are turned over and carried by a temporary carrier CR6, for example a tape.

Afterwards, as shown in the drawing labeled as “(4)” of FIG. 4, The stressing film 167 is formed on the backside of the semiconductor element 160. For example, the stressing film 167 could be formed by pasting a polymer tape on the semiconductor element 160, or by depositing a polymer material on the semiconductor element 160.

Then, as shown in the drawing labeled as “(5)” of FIG. 4, the temporary carrier CR6 is removed. Further, the stressing film 167 could be cured. After curing, the stressing film 167 is deformed and makes the semiconductor element 160 being warped. In another embodiment, the stressing film 167 could be deformed without curing.

Moreover, as shown in the drawing labeled as “(6)” of FIG. 4, the bonding film 153 is formed on the semiconductor element 150. The bonding film 153 is, for example, formed by disposition. The semiconductor element 150 is, for example, a chip.

Next, as shown in the drawing labeled as “(7)” of FIG. 4, the semiconductor element 150 is bounded on the semiconductor element 160 by bonding the bonding film 153 and the bonding film 163. When the bonding film 153 and the bonding film 163 are going to be bonded, the bonding film 153 and the bonding film 163 are in point-to-point contact first due to the convex surface S163 of the bonding film 163. Then, the contact area is gradually expanded as the bonding film 153 and the bonding film 163 approach.

Afterwards, as shown in the drawing labeled as “(8)” of FIG. 4, the semiconductor element 150 is already bonded on the semiconductor element 160, and any air gap would not be existed in the bonding interface, and the quality of bonding can be improved. The semiconductor device including the semiconductor element 150 and the semiconductor element 160 could continue to be processed by other processes.

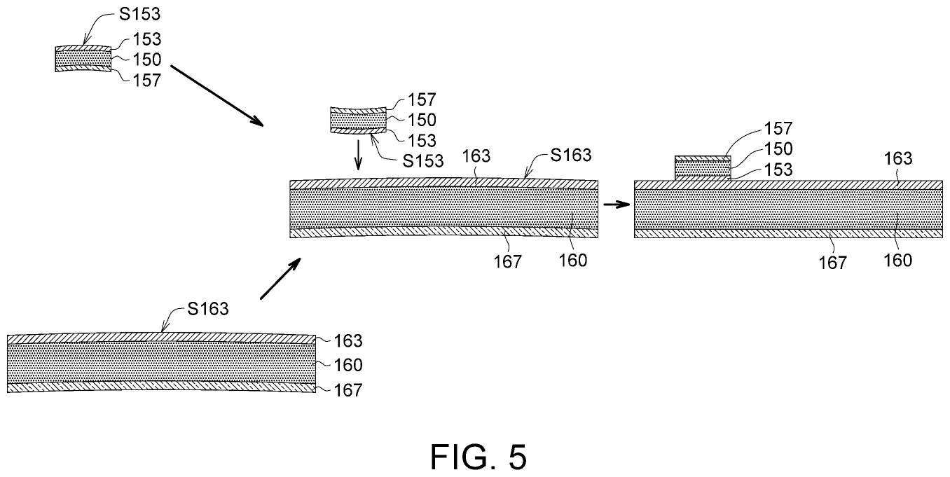

Please refer to FIG. 5, which illustrates the chip bonding process in the semiconductor manufacturing method according to another embodiment. As shown in the upper left drawing of FIG. 5, the semiconductor element 150 with the bonding film 153 and the stressing film 157 is formed. The bonding film 153 and the stressing film 157 are formed on two opposite sides of the semiconductor element 150. The stressing film 157 makes the semiconductor element 150 being warped and makes the bonding film 153 having the convex surface S153.

Further, as shown in the lower left drawing of FIG. 5, the semiconductor element 160 with the bonding film 163 and the stressing film 167 is formed. The bonding film 163 and the stressing film 167 are formed on two opposite sides of the semiconductor element 160. The stressing film 167 makes the semiconductor element 160 being warped and makes the bonding film 163 having the convex surface S163.

Then, as shown in the right drawing of FIG. 5, the semiconductor element 150 and the semiconductor element 160 are bonded by bonding the bonding film 153 and the bonding film 163. When the bonding film 153 and the bonding film 163 are going to be bonded, the bonding film 153 and the bonding film 163 are in point-to-point contact first due to the convex surface S153 of the bonding film 153 and the convex surface S163 of the bonding film 163. Then, the contact area is gradually expanded as the bonding film 153 and the bonding film 163 approach. Therefore, any air gap would not be existed in the bonding interface, and the quality of bonding can be improved.

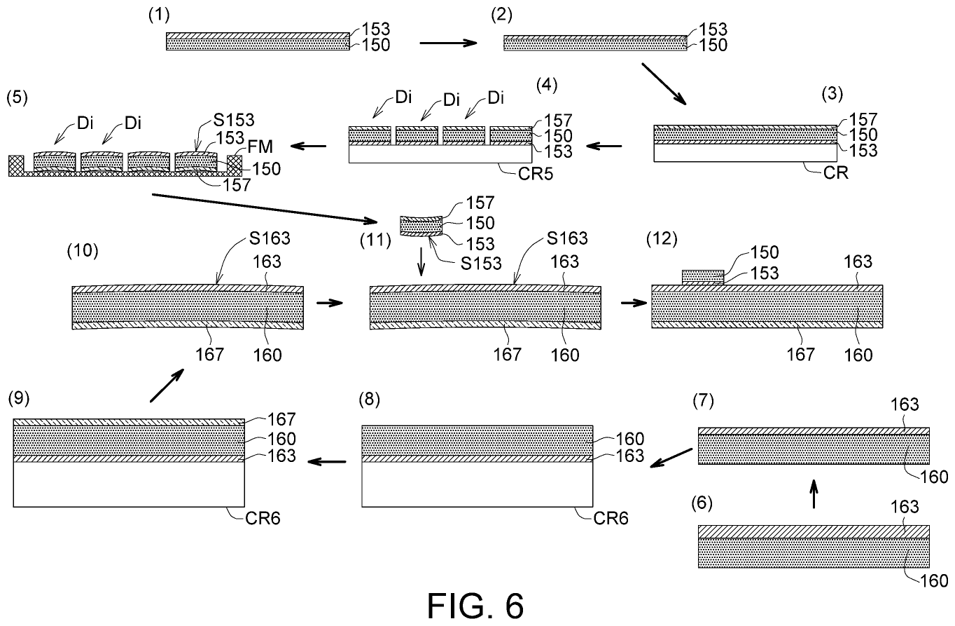

Please refer to FIG. 6, which illustrates the detail steps of FIG. 5. The drawings in FIG. 6 are labeled as “(1)” to “(12)”. The drawings labeled as “(1)” to “(5)” of FIG. 6 are similar to the drawings labeled as “(1)” to “(5)” of FIG. 2, and the similarities are not repeated here.

The drawings labeled as “(6)” to “(10)” of FIG. 6 are similar to the drawings labeled as “(1)” to “(5)” of FIG. 4, and the similarities are not repeated here.

Next, as shown in the drawing labeled as “(11)” of FIG. 6, the semiconductor element 150 is bounded on the semiconductor element 160 by bonding the bonding film 153 and the bonding film 163. When the bonding film 153 and the bonding film 163 are going to be bonded, the bonding film 153 and the bonding film 163 are in point-to-point contact first due to the convex surface S153 of the bonding film 153 and the convex surface S163 of the bonding film 163. Then, the contact area is gradually expanded as the bonding film 153 and the bonding film 163 approach.

Afterwards, as shown in the drawing labeled as “(12)” of FIG. 6, the semiconductor element 150 is already bonded on the semiconductor element 160, and any air gap would not be existed in the bonding interface, and the quality of bonding can be improved. The semiconductor device including the semiconductor element 150 and the semiconductor element 160 could continue to be processed by other processes.

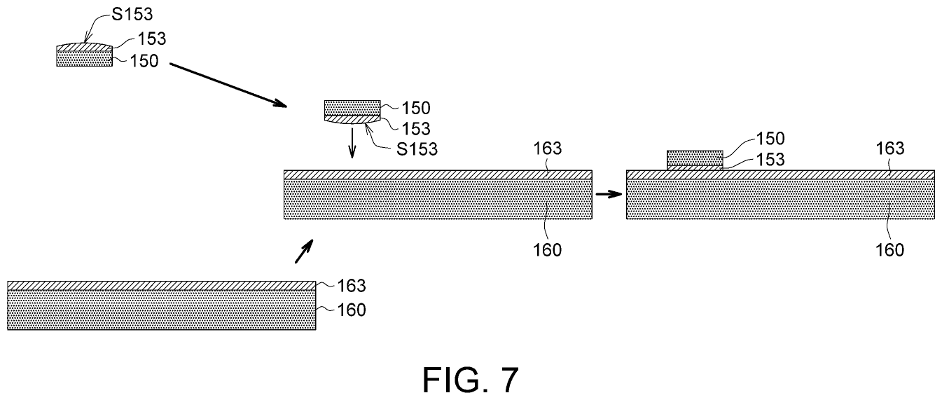

Please refer to FIG. 7, which illustrates the chip bonding process in the semiconductor manufacturing method according to another embodiment. As shown in the upper left drawing of FIG. 7, the semiconductor element 150 with the bonding film 153 is formed. The bonding film 153 having the convex surface S153 is formed on one side of the semiconductor element 150. The semiconductor element 150 is, for example, a chip. The bonding film 153 is etched to form the convex surface S153. In this embodiment, the stressing film 157 is not needed and the semiconductor element 150 is not warped.

Further, as shown in the lower left drawing of FIG. 7, the semiconductor element 160 with the bonding film 163 is formed. The semiconductor element 160 is, for example, a wafer. The bonding film 163 is formed on one side of the semiconductor element 160.

Then, as shown in the right drawings of FIG. 7, the semiconductor element 150 and the semiconductor element 160 are bonded by bonding the bonding film 153 and the bonding film 163. When the bonding film 153 and the bonding film 163 are going to be bonded, the bonding film 153 and the bonding film 163 are in point-to-point contact first due to the convex surface S153 of the bonding film 153. Then, the contact area is gradually expanded as the bonding film 153 and the bonding film 163 approach. Therefore, any air gap would not be existed in the bonding interface, and the quality of bonding can be improved.

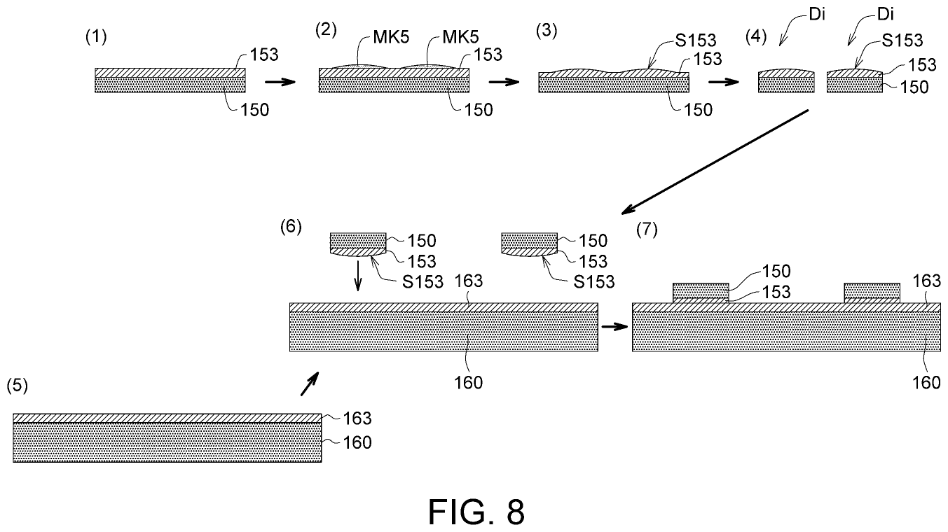

Please refer to FIG. 8, which illustrates the detail steps of FIG. 7. The drawings in FIG. 8 are labeled as “(1)” to “(7)”. As shown in the drawing labeled as “(1)” of FIG. 8, the bonding film 153 is formed on the semiconductor element 150. The bonding film 153 is, for example, formed by disposition.

Then, as shown in the drawing labeled as “(2)” of FIG. 8, a mask bump MK5 is formed on the bonding film 153. In one embodiment, the bonding film 153 could be grinded by chemical mechanical polishing (CMP) before forming the mask bump MK5. A surface of the mask bump MK5 is convex. In one embodiment, the mask bump MK5 could be formed by dropping a photoresist on the bonding film 153. The dropped photoresist will naturally form a convex surface.

Next, as shown in the drawing labeled as (3) of FIG. 8, the mask bump MK5 and the bonding film 153 are etched, such that the convex surface S153 of the bonding film 153 is formed. For example, the mask bump MK5 and the bonding film 153 could be etched by plasma dry etching.

Then, as shown in the drawing labeled as (4) of FIG. 8, the semiconductor element 150 and the bonding film 153 are cut into a plurality of chips Di.

Further, as shown in the drawing labeled as (5) of FIG. 8, the bonding film 163 is formed on the semiconductor element 160. The bonding film 163 is, for example, formed by disposition. The semiconductor element 160 is, for example, a wafer.

Next, as shown in the drawing labeled as “(6)” of FIG. 8, the semiconductor element 150 is bounded on the semiconductor element 160 by bonding the bonding film 153 and the bonding film 163. When the bonding film 153 and the bonding film 163 are going to be bonded, the bonding film 153 and the bonding film 163 are in point-to-point contact first due to the convex surface S153 of the bonding film 153. Then, the contact area is gradually expanded as the bonding film 153 and the bonding film 163 approach.

Afterwards, as shown in the drawing labeled as “(7)” of FIG. 8, the semiconductor element 150 is already bonded on the semiconductor element 160, and any air gap would not be existed in the bonding interface, and the quality of bonding can be improved. The semiconductor device including the semiconductor element 150 and the semiconductor element 160 could continue to be processed by other processes.

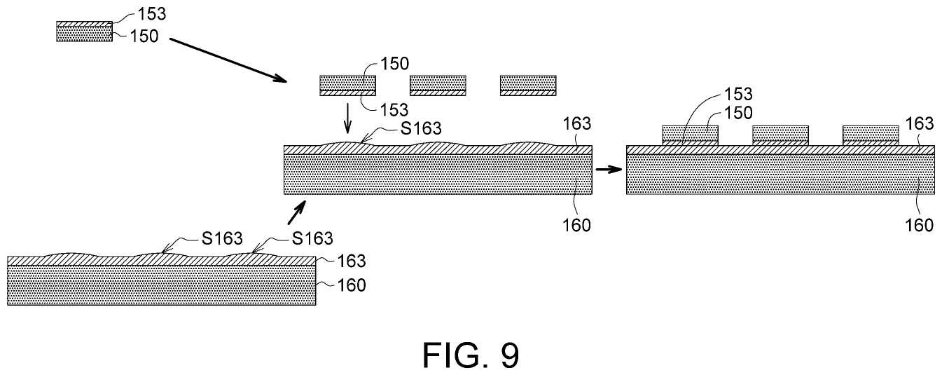

Please refer to FIG. 9, which illustrates the chip bonding process in the semiconductor manufacturing method according to another embodiment. As shown in the upper left drawing of FIG. 9, the semiconductor element 150 with the bonding film 153 is formed. The semiconductor element 150 is, for example, a chip.

Further, as shown in the lower left drawing of FIG. 9, the semiconductor element 160 with the bonding film 163 is formed. The semiconductor element 160 is, for example, a wafer. The bonding film 163 having the convex surface S163 is formed on one side of the semiconductor element 160. The bonding film 163 is etched to form the convex surface S163. In this embodiment, the stressing film 167 is not needed and the semiconductor element 160 is not warped.

Then, as shown in the right drawings of FIG. 9, the semiconductor element 150 and the semiconductor element 160 are bonded by bonding the bonding film 153 and the bonding film 163. When the bonding film 153 and the bonding film 163 are going to be bonded, the bonding film 153 and the bonding film 163 are in point-to-point contact first due to the convex surface S153 of the bonding film 153. Then, the contact area is gradually expanded as the bonding film 153 and the bonding film 163 approach. Therefore, any air gap would not be existed in the bonding interface, and the quality of bonding can be improved.

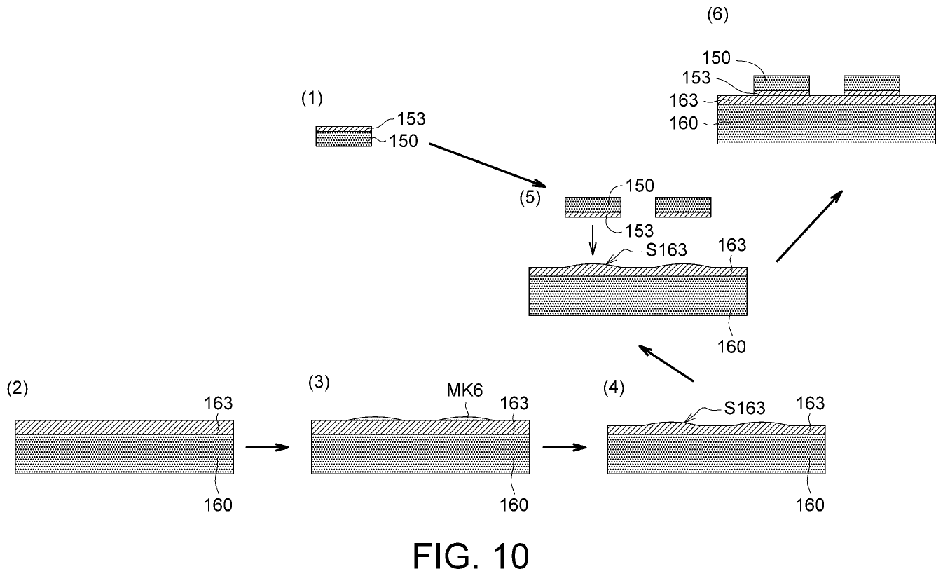

Please refer to FIG. 10, which illustrates the detail steps of FIG. 9. The drawings in FIG. 10 are labeled as “(1)” to “(6)”. As shown in the drawing labeled as “(1)” of FIG. 8, the bonding film 153 is formed on the semiconductor element 150. The bonding film 153 is, for example, formed by disposition.

Moreover, as shown in the drawing labeled as “(2)” of FIG. 10, the bonding film 163 is formed on the semiconductor element 160. The bonding film 163 is, for example, formed by disposition.

Then, as shown in the drawing labeled as “(3)” of FIG. 10, the mask bump MK6 is formed on the bonding film 163. In one embodiment, the bonding film 163 could be grinded by chemical mechanical polishing (CMP) before forming the mask bump MK6. The surface of the mask bump MK6 is convex. In one embodiment, the mask bump MK6 could be formed by dropping a photoresist on the bonding film 163. The dropped photoresist will naturally form a convex surface.

Next, as shown in the drawing labeled as (4) of FIG. 10, the mask bump MK6 and the bonding film 163 are etched, such that the convex surface S163 of the bonding film 163 is formed. For example, the mask bump MK6 and the bonding film 163 could be etched by plasma dry etching.

Next, as shown in the drawing labeled as “(5)” of FIG. 10, the semiconductor element 150 is bounded on the semiconductor element 160 by bonding the bonding film 153 and the bonding film 163. When the bonding film 153 and the bonding film 163 are going to be bonded, the bonding film 153 and the bonding film 163 are in point-to-point contact first due to the convex surface S153 of the bonding film 153. Then, the contact area is gradually expanded as the bonding film 153 and the bonding film 163 approach.

Afterwards, as shown in the drawing labeled as “(6)” of FIG. 10, the semiconductor element 150 is already bonded on the semiconductor element 160, and any air gap would not be existed in the bonding interface, and the quality of bonding can be improved. The semiconductor device including the semiconductor element 150 and the semiconductor element 160 could continue to be processed by other processes.

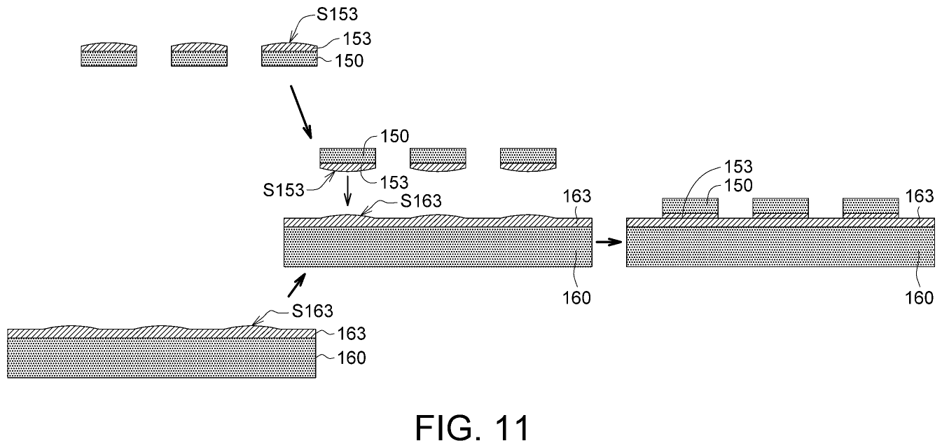

Please refer to FIG. 11, which illustrates the chip bonding process in the semiconductor manufacturing method according to another embodiment. As shown in the upper left drawing of FIG. 11, the semiconductor element 150 with the bonding film 153 is formed. The bonding film 153 having the convex surface S153 is formed on one side of the semiconductor element 150. The semiconductor element 150 is, for example, a chip. The bonding film 153 is etched to form the convex surface S153. In this embodiment, the stressing film 157 is not needed and the semiconductor element 150 is not warped.

Further, as shown in the lower left drawing of FIG. 11, the semiconductor element 160 with the bonding film 163 is formed. The bonding film 163 having the convex surface S163 is formed on one side of the semiconductor element 160. The semiconductor element 160 is, for example, a wafer. The bonding film 163 is etched to form the convex surface S163. In this embodiment, the stressing film 167 is not needed and the semiconductor element 160 is not warped.

Then, as shown in the right drawing of FIG. 11, the semiconductor element 150 and the semiconductor element 160 are bonded by bonding the bonding film 153 and the bonding film 163. When the bonding film 153 and the bonding film 163 are going to be bonded, the bonding film 153 and the bonding film 163 are in point-to-point contact first due to the convex surface S153 of the bonding film 153 and the convex surface S163 of the bonding film 163. Then, the contact area is gradually expanded as the bonding film 153 and the bonding film 163 approach. Therefore, any air gap would not be existed in the bonding interface, and the quality of bonding can be improved.

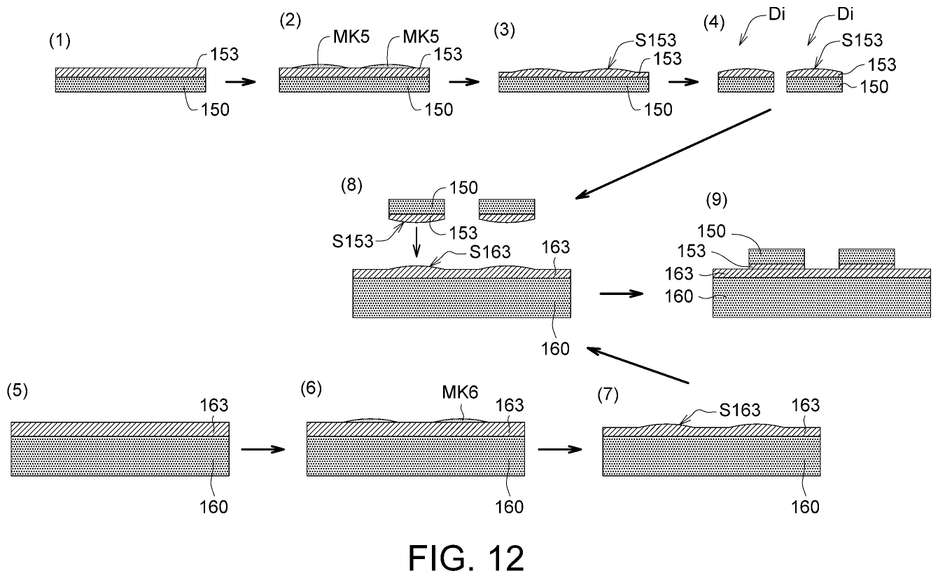

Please refer to FIG. 12, which illustrates the detail steps of FIG. 11. The drawings in FIG. 10 are labeled as “(1)” to “(9)”. The drawings labeled as “(1)” to “(4)” of FIG. 12 are similar to the drawings labeled as “(1)” to “(4)” of FIG. 8, and the similarities are not repeated here.

The drawings labeled as “(5)” to “(7)” of FIG. 12 are similar to the drawings labeled as “(2)” to “(4)” of FIG. 10, and the similarities are not repeated here.

Then, as shown in the drawing labeled as “(8)” of FIG. 12, the semiconductor element 150 is bounded on the semiconductor element 160 by bonding the bonding film 153 and the bonding film 163. When the bonding film 153 and the bonding film 163 are going to be bonded, the bonding film 153 and the bonding film 163 are in point-to-point contact first due to the convex surface S153 of the bonding film 153 and the convex surface S163 of the bonding film 163. Then, the contact area is gradually expanded as the bonding film 153 and the bonding film 163 approach.

Afterwards, as shown in the drawing labeled as “(9)” of FIG. 12, the semiconductor element 150 is already bonded on the semiconductor element 160, and any air gap would not be existed in the bonding interface, and the quality of bonding can be improved. The semiconductor device including the semiconductor element 150 and the semiconductor element 160 could continue to be processed by other processes.

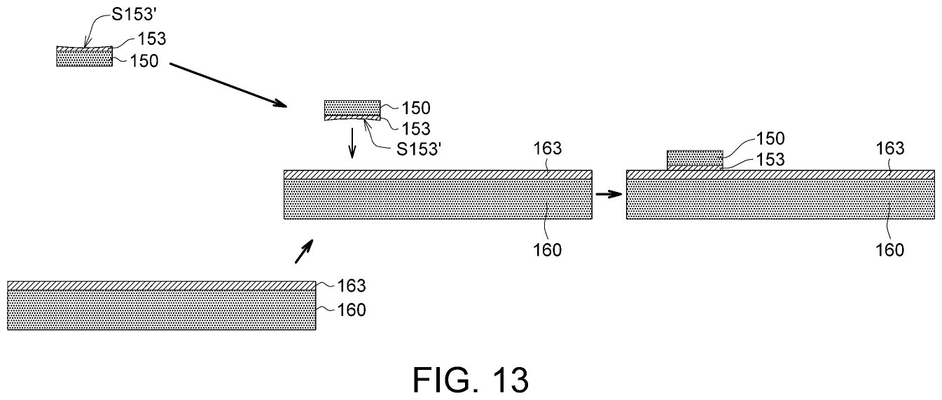

Please refer to FIG. 13, which illustrates the chip bonding process in the semiconductor manufacturing method according to another embodiment. As shown in the upper left drawing of FIG. 13, the semiconductor element 150 with the bonding film 153 is formed. The bonding film 153 having the concave surface S153′ is formed on one side of the semiconductor element 150. The semiconductor element 150 is, for example, a chip. The bonding film 153 is etched to form the concave surface S153′. In this embodiment, the semiconductor element 150 is not warped.

Further, as shown in the lower left drawing of FIG. 13, the semiconductor element 160 with the bonding film 163 is formed. The semiconductor element 160 is, for example, a wafer. The bonding film 163 is formed on one side of the semiconductor element 160.

Then, as shown in the right drawings of FIG. 13, the semiconductor element 150 and the semiconductor element 160 are bonded by the bonding film 153 and the bonding film 163. When the bonding film 153 and the bonding film 163 are going to be bonded, the bonding film 153 and the bonding film 163 are contacted from the edge of the bonding film 153 due to the concave surface S153′ of the bonding film 153. Then, the contact area is gradually expanded as the bonding film 153 and the bonding film 163 approach. Therefore, the edge of the bonding film 153 could be firmly bonded, and the quality of bonding can be improved.

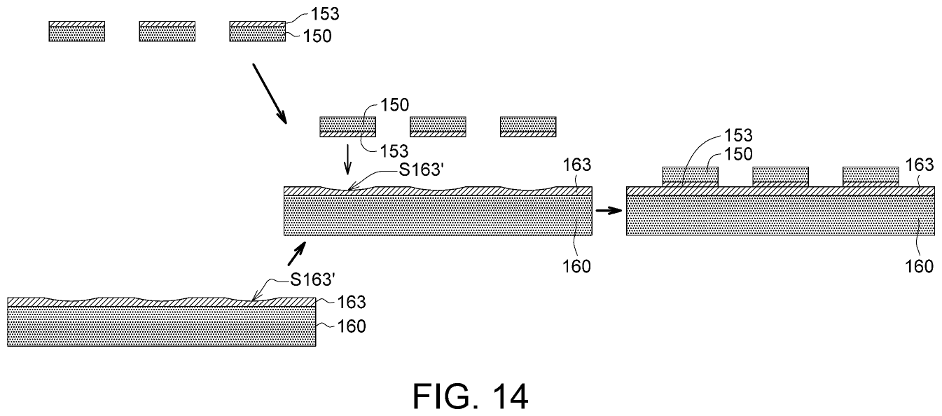

Please refer to FIG. 14, which illustrates the chip bonding process in the semiconductor manufacturing method according to another embodiment. As shown in the upper left drawing of FIG. 14, the semiconductor element 150 with the bonding film 153 is formed. The bonding film 153 is formed on one side of the semiconductor element 150. The semiconductor element 150 is, for example, a chip.

Further, as shown in the lower left drawing of FIG. 14, the semiconductor element 160 with the bonding film 163 is formed. The semiconductor element 160 is, for example, a wafer. The bonding film 163 having the concave surface S163′ is formed on one side of the semiconductor element 160. The bonding film 163 is etched to form the concave surface S163′. In this embodiment, the semiconductor element 160 is not warped.

Then, as shown in the right drawing of FIG. 14, the semiconductor element 150 and the semiconductor element 160 are bonded by the bonding film 153 and the bonding film 163. When the bonding film 153 and the bonding film 163 are going to be bonded, the bonding film 153 and the bonding film 163 are contacted from the edge of the bonding film 153 due to the concave surface S163′ of the bonding film 163. Then, the contact area is gradually expanded as the bonding film 153 and the bonding film 163 approach. Therefore, the edge of the bonding film 153 could be firmly bonded, and the quality of bonding can be improved.

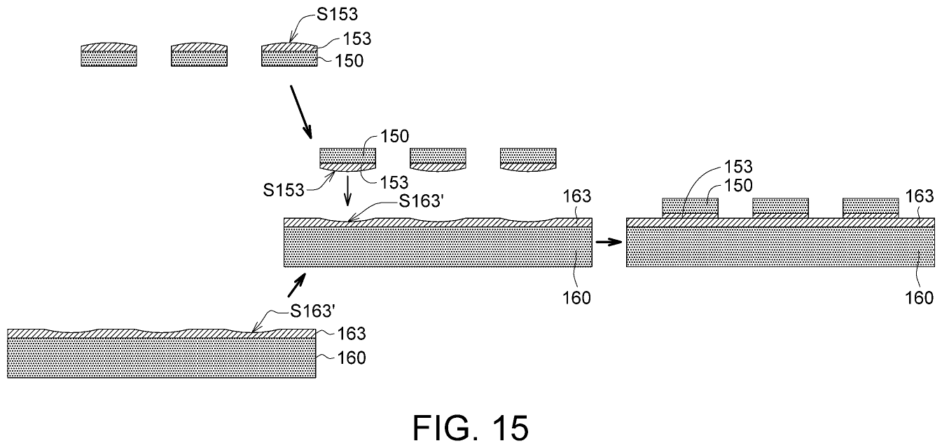

Please refer to FIG. 15, which illustrates the chip bonding process in the semiconductor manufacturing method according to another embodiment. As shown in the upper left drawing of FIG. 15, the semiconductor element 150 with the bonding film 153 is formed. The bonding film 153 having the convex surface S153 is formed on one side of the semiconductor element 150. The semiconductor element 150 is, for example, a chip. The bonding film 153 is etched to form the convex surface S153′. In this embodiment, the semiconductor element 150 is not warped.

Further, as shown in the lower left drawing of FIG. 15, the semiconductor element 160 with the bonding film 163 is formed. The semiconductor element 160 is, for example, a wafer. The bonding film 163 having the concave surface S163′ is formed on one side of the semiconductor element 160. The bonding film 163 is etched to form the concave surface S163′. In this embodiment, the semiconductor element 160 is not warped.

Then, as shown in the right drawing of FIG. 15, the semiconductor element 150 and the semiconductor element 160 are bonded by the bonding film 153 and the bonding film 163. When the bonding film 153 and the bonding film 163 are going to be bonded, the bonding film 153 and the bonding film 163 have large contacting area due to the convex surface S153′ of the bonding film 153 and the concave surface S163′ of the bonding film 163. Therefore, the quality of bonding can be improved.

According to the description described above, the bonding film 153 (or the bonding film 163) having the convex surface (or the concave surface) is used. The bonding film 153 and the bonding film 163 could be in point-to-point contact first due to the convex surface S153 of the bonding film 153 (or the convex surface S163 of the bonding film 163). The bonding film 153 and the bonding film 163 could be contacted from the edge of the bonding film 153 (or the bonding film 163) due to the concave surface S153′ of the bonding film 153 (or the concave surface S163′ of the bonding film 163). The bonding film 153 and the bonding film 163 have large contacting area due to the convex surface S153′ of the bonding film 153 and the concave surface S163′ of the bonding film 163. The quality of bonding can be improved based on those designs.

According to one embodiment, a semiconductor manufacturing method is provided. The semiconductor manufacturing method includes the following steps. A first semiconductor element with a bonding film and a first stressing film is formed. The first bonding film and the first stressing film are formed on two opposite sides of the first semiconductor element. The first stressing film makes the first bonding film to have a first convex surface. A second semiconductor element with a second bonding film is formed. The second bonding film is formed on one side of the second semiconductor element. The first semiconductor element and the second semiconductor element are bonded by bonding the first bonding film and the second bonding film.

According to another embodiment, a semiconductor manufacturing method is provided. The semiconductor manufacturing method includes the following steps. A first semiconductor element with a first bonding film is formed. The first bonding film having a first convex surface is formed on one side of the first semiconductor element. A second semiconductor element with a second bonding film is formed. The second bonding film is formed on one side of the second semiconductor element. The first semiconductor element and the second semiconductor element are bonded by bonding the first bonding film and the second bonding film.

According to an alternative embodiment, a semiconductor manufacturing method is provided. The semiconductor manufacturing method includes the following steps. A first semiconductor element with a first bonding film is formed. The first bonding film having a first concave surface is formed on one side of the first semiconductor element. A second semiconductor element with a second bonding film is formed. The second bonding film is formed on one side of the second semiconductor element. The first semiconductor element and the second semiconductor element are bonded by bonding the first bonding film and the second bonding film.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor manufacturing method, comprising:
forming a first semiconductor element with a first bonding film and a first stressing film, wherein the first bonding film and the first stressing film are formed on two opposite sides of the first semiconductor element, and the first stressing film makes the first bonding film to have a first convex surface;
forming a second semiconductor element with a second bonding film, wherein the second bonding film is formed on one side of the second semiconductor element; and
bonding the first semiconductor element and the second semiconductor element by bonding the first bonding film and the second bonding film.

2. The semiconductor manufacturing method according to claim 1, wherein the first stressing film makes the first semiconductor element being warped.

3. The semiconductor manufacturing method according to claim 1, wherein the first semiconductor element is a chip, and the second semiconductor element is a wafer.

4. The semiconductor manufacturing method according to claim 1, wherein the first semiconductor element is a wafer, and the second semiconductor element is a chip.

5. The semiconductor manufacturing method according to claim 1, wherein a second stressing film is formed on another side of the second semiconductor element, and the second stressing film makes the second bonding film to have a second convex surface.

6. The semiconductor manufacturing method according to claim 1, wherein the step of forming the first semiconductor element with the first bonding film and the first stressing film comprises:
forming the first bonding film on the first semiconductor element;
forming the first stressing film on the first semiconductor element; and
curing the first stressing film.

7. The semiconductor manufacturing method according to claim 6, wherein the first stressing film is formed by pasting a polymer tape on the first semiconductor element.

8. The semiconductor manufacturing method according to claim 6, wherein the first stressing film is formed by depositing a polymer material on the first semiconductor element.

9. The semiconductor manufacturing method according to claim 1, wherein a coefficient of thermal expansion (CTE) of the first stressing film is larger than that of silicon.

10. A semiconductor manufacturing method, comprising:
forming a first semiconductor element with a first bonding film, wherein the first bonding film having a first convex surface is formed on one side of the first semiconductor element;
forming a second semiconductor element with a second bonding film, wherein the second bonding film is formed on one side of the second semiconductor element; and
bonding the first semiconductor element and the second semiconductor element by bonding the first bonding film and the second bonding film.

11. The semiconductor manufacturing method according to claim 10, wherein the first semiconductor element is a chip, and the second semiconductor element is a wafer.

12. The semiconductor manufacturing method according to claim 10, wherein the first semiconductor element is a wafer, and the second semiconductor element is a chip.

13. The semiconductor manufacturing method according to claim 10, wherein the second bonding film has a second convex surface.

14. The semiconductor manufacturing method according to claim 10, wherein the step of forming the first semiconductor element with the first bonding film comprises:
forming a mask bump on the first bonding film; and
etching the mask bump and the first bonding film, such that the first convex surface of the first bonding film is formed.

15. The semiconductor manufacturing method according to claim 14, wherein a surface of the mask bump is convex.

16. The semiconductor manufacturing method according to claim 14, wherein the mask bump is formed by dropping a photoresist on the first bonding film.

17. A semiconductor manufacturing method, comprising:
forming a first semiconductor element with a first bonding film, wherein the first bonding film having a first concave surface is formed on one side of the first semiconductor element;
forming a second semiconductor element with a second bonding film, wherein the second bonding film is formed on one side of the second semiconductor element; and
bonding the first semiconductor element and the second semiconductor element by bonding the first bonding film and the second bonding film.

18. The semiconductor manufacturing method according to claim 17, wherein the first semiconductor element is a chip, and the second semiconductor element is a wafer.

19. The semiconductor manufacturing method according to claim 17, wherein the first semiconductor element is a wafer, and the second semiconductor element is a chip.

20. The semiconductor manufacturing method according to claim 16, wherein the second bonding film has a second convex surface.
